(19) United States
(12) Patent Application Publication
(10) Pub. No.: US 2005/0170104 A1
(43) Pub. Date: Aug. 4, 2005

(54) Stress-tuned, single-layer silicon nitride film

(75) Inventors: KeeBum Jung, Gilroy, CA (US); Sum-Yee Betty Tang, San Jose, CA (US); Martin Jay Seamons, San Jose, CA (US); Reza Arghavani, Scotts Valley, CA (US); Eller Y. Juco, San Jose, CA (US)

Correspondence Address: PATENT COUNSEL;APPLIED MATERIALS, INC., Legal Affairs Department, P.O. BOX 450A, Santa Clara, CA, 95052, US

(73) Assignee: APPLIED MATERIALS, INC.

(21) Appl. No.: 10/768,577

(22) Filed: Jan. 29, 2004

(51) Int. Cl. H05H 1/24; C23C 16/00

(52) U.S. Cl. 427/569; 118/723 E

(57) ABSTRACT

We have discovered that is possible to tune the stress of a single-layer silicon nitride film by manipulating certain film deposition parameters. These parameters include: use of multiple (typically dual) power input sources operating within different frequency ranges; the deposition temperature; the process chamber pressure; and the composition of the deposition source gas. In particular, we have found that it is possible to produce a single-layer, thin (300 Å to 1000 Å thickness) silicon nitride film having a stress tuned to be within the range of about −1.4 GPa (compressive) to about +1.5 GPa (tensile) by depositing the film by PECVD, in a single deposition step, at a substrate temperature within the range of about 375° C. to about 525 ° C., and over a process chamber pressure ranging from about 2 Torr to about 15 Torr.

### FIELD OF THE INVENTION

The present invention pertains to a stress-tuned, single-layer silicon nitride film and to a method of depositing the silicon nitride film using plasma-enhanced chemical vapor deposition (PECVD).

### BRIEF DESCRIPTION OF THE BACKGROUND ART

An important element of transistor scaling and improved drive current performance for semiconductor devices is the mobility of the carriers in the channels of the device. One approach for enhancing the mobility is the induction of strain in a silicon lattice, to modify the structure of silicon and thus enhance the electron mobility or hole mobility.

U.S. Pat. No. 5,155,571, to Wang et al., issued Oct. 13, 1992, describes the increase in carrier mobility for both electrons and holes in complementary field effect transistor structures, such as CMOS and CMOD. The increased carrier mobility is obtained by using strained GeₓSi₁₋ₓ/Si layers for the carrier conduction channels. There is said to be an advantage in increasing the carrier mobilities for the holes and electrons in substantially the same magnitude for complementary logic applications. The complementary FET structures are said to be advantageously employed within bipolar devices in integrated circuits. (Abstract).

U.S. Pat. No. 6,111,267, to Fischer et al., issued Aug. 29, 2000, describes an integrated CMOS circuit and a method for producing the circuit, including a semiconductor structure having a p-channel MOS transistor and an n-channel MOS transistor. The structure includes a first silicon layer, a stressed Si₁₋ₓGeₓ layer, and a second silicon layer, which are grown by selective epitaxy. (Abstract).

U.S. Pat. No. 6,335,266, to Kitahara et al., issued Jan. 1, 2002, discloses polycrystalline semiconductor material containing Si, Ge, or SiGe, where the material contains hydrogen (H) atoms and the number of monohydride structures of couplings between Si or Ge and H is larger than the number of higher order hydride structures. By configuring the compositions of a polycrystalline semiconductor material in this manner, the carrier mobility is said to be increased. (Abstract).

U.S. Pat. No. 6,475,869, to Bin Yu, issued Nov. 5, 2002, describes a method of manufacturing an integrated circuit with a channel region containing germanium. The semiconductor material containing germanium is said to enable an increase in charge mobility associated with the transistor. An epitaxy process can be used to form the channel region, with a silicon-on-insulator structure being employed. (Abstract).

U.S. Patent Application Publication No. U.S. 2002/0167048 A1, of Tweet et al., published Nov. 14, 2002, describes a thin Si/SiGe stack on top of an equally thin top Si layer of an SOI substrate. The SiGe layer is said to be compressively strained, but partially relaxed, and the Si layers are said to each be tensilely strained, without high dislocation densities. (Abstract).

U.S. Pat. No. 6,544,854, to Puchner et al., issued Apr. 8, 2003, describes a method of fabricating a semiconducting devices on a substrate, where the improvement includes forming a strained silicon germanium channel layer on the substrate. A gate insulation layer is formed on top of the strained silicon germanium channel layer at a temperature which does not exceed about 800° C. (Abstract).

It is readily apparent from the above disclosures that it is known in the art to use strained silicon-germanium structures to improve carrier mobilities in semiconductor devices, when the devices are formed at temperatures in the 800° C. range. Formation at this temperature ensures electron mobility in the range of 200-350 cm²/Vs, which is close to the electron mobility of thin film transistors formed on single crystal silicon (up to 500 cm²/Vs, S. M. Sze, Physics of Semiconductor Devices, p. 29, Second Edition, Wiley).

Silicon nitride films have been used in the fabrication of semiconductor devices to solve a number of different problems. Typically, nitride films have been used as etch stop layers and barrier layers. For example, U.S. Pat. No. 6,071,784, to Mehta et al., describes the annealing of silicon oxynitride and silicon nitride films to reduce hot carrier effects. U.S. Pat. No. 6,372,672, to Kim et al., issued Apr. 16, 2002, describes a method of forming a PECVD silicon nitride layer which exhibits reduced stress variation during an annealing process, for films used as a passivation film or interlayer (electrical) insulating film in integrated circuit devices. U.S. Patent Application Publication No. U.S. 2002/0053720 A1, of Boursat et al., published May 9, 2002, describes a substrate comprising a wafer of silicon having a top face covered with an electrically insulating layer of silicon nitride. The silicon nitride layer supports one or more conductive tracts obtained by metallizing the top face of the silicon nitride layer. The silicon nitride layer is built up of a succession of different types of silicon nitride, where the succession of layers are under compression and tension so that the stresses on the silicon wafer compensate.

A number of papers have been published which relate to silicon nitride films formed by PECVD. For example, R. S. Martin E. P. van de Ven presented a paper at the V-MIC Conference, Jun. 13-14, 1988, entitled “RF Bias to Control Stress and Hydrogen in PECVD Nitride”. This paper addressed stress-induced voids in aluminum interconnect and hot carrier induced degradation in plasma nitride passivated VLSI circuits. The paper presented the use of a dual frequency PECVD process which uses high frequency (13.56 MHz) for excitation of the reactant species (SiH₄, NH₃, N₂); and, a low frequency (450 kHz) RF bias on the substrate, to control bombardment of the silicon nitride film surface during deposition. The film was a 9800 Å thick film which was a combination of seven individually deposited layers (each layer having a thickness of about 1400 Å): The process is described as providing stress control and reduction of Si—H content of the film without significantly affecting other film properties. (Abstract) A second paper authored by Evert P. van de Ven et al., presented at the VMIC Conference, Jun. 12-13, 1990, entitled “Advantages of Dual Frequency PECVD for Deposition of ILD and Passivation Films”, suggests that control of silicon nitride film stress, improved step coverage, film density, chemical composition, and stability can be optimized by controlling deposition pressure and the ratio of high and low frequency RF power. (Abstract) The data presented are evidently for films prepared using Novellus Systems, Inc. PECVD apparatus, which provides a seven layer PECVD silicon nitride film as described above.

Another paper published in the Journal of Applied Physics, Vol. 71, No. 4, 15 February 1992, by C. W. Pearce et al., titled “Characteristics of silicon nitride deposited by plasma-enhanced chemical vapor deposition using a dual frequency radio frequency source”, provides data for the effect of plasma excitation frequency on the properties of plasma-enhanced chemical vapor deposition silicon nitride films. The paper relates to plasma-deposited silicon nitride films having a thickness of about 10,000 Å, where each film is composed of seven individual layers (each layer having a thickness of about 1400 Å). The film is used extensively as a final passivation layer for integrated circuits. The authors conclude that the inclusion of N—H₂ structures in PECVD nitride is responsible for the compressive state in the film. As the quantity of these structures is reduced, either by altering the plasma process or by annealing the films, the stress becomes increasingly tensile. This is said to relate to the movement of H from a N—H bond to an unsaturated silicon bond. The location of the H is said to play a major role in determining film properties such as stress, wet etch rate, and conduction. (Conclusions).

More recently, silicon nitride layers have been used in structures which improve the electron mobility in n-channel MOSFET devices. U.S. Patent Application Publication No. U.S. 2003/0040158 A1, of Saitoh, published Feb. 27, 2003, describes the use of a combination of silicon nitride layers, some exhibiting tensile stress and some exhibiting compressive stress to form an n-channel MOSFET. A first nitride layer exhibiting a tensile stress is formed on a substrate to cover the n-channel MOSFET. A second nitride layer exhibiting a compressive stress is formed on a substrate to cover the p-channel MOSFET. The combination of the first and second nitride layers is said to decrease bend or warp in the substrate. Preferably, the first nitride layer, which is under tensile stress, is formed by a low pressure CVD (LPCVD) process, while the second nitride layer, which is under compressive stress, is formed by a PECVD process. (Abstract).

U.S. Pat. No. 6,573,172, to En et al., issued Jun. 3, 2003, describes a method for improving carrier mobility of PMOS and NMOS devices which is very similar to that mentioned above with respect to the Saitoh reference. In the En et al. description, methods are described for fabricating semiconductor devices in which a tensile film is formed over PMOS transistors to cause a compressive stress therein, and a compressive film is formed over NMOS transistors to achieve a tensile stress therein, by which improved carrier mobility if said to be facilitated in both devices. (Abstract).

In the past, silicon nitride individual layers typically had a thickness in the range of about 1400 Å, with an overall film thickness in the range of about 10,000 Å. While it is possible to deposit the thicker films of at least 1400 Å, for example, whle controlling the stress within the film, it is more difficult to deposit a thinner film with good control over the amount of stress in the film. None of the above references provide a deposition method which would allow one to deposit thinner films while carefully controlling the stress of the film.

It would therefore be desirable to provide a method of tuning the stress of a single-layer silicon nitride film which is deposited to have a thickness of 1000 Å or less.

### SUMMARY OF THE INVENTION

We have discovered that is possible to tune the stress of a single-layer, homogeneous silicon nitride film by manipulating certain film deposition parameters. In particular, these parameters include: use of multiple (typically dual) power input sources operating within different frequency ranges (“dual frequency power”); the deposition temperature; the process chamber pressure; and the composition of the deposition source gas.

In particular, we have found that it is possible to produce a single-layer, thin (300 Å to 1000 Å thickness) silicon nitride film having a stress tuned to be within the range of about −1.4 GPa (compressive) to about +1.5 GPa (tensile) by depositing the film by PECVD, in a single deposition step, at a substrate temperature within the range of about 375° C. to about 525° C., and over a process chamber pressure ranging from about 2 Torr to about 15 Torr (more typically, about 2 Torr to about 10 Torr).

The film is deposited in a PECVD chamber having multiple (typically dual) power input sources operating within different frequency ranges to provide power to a plasma used in the film formation process. Typically, a high frequency power input source operates at a frequency within the range of about 13 MHz to about 14 MHz. A low frequency power input source operates at a frequency within the range of about 300 kHz to about 400 kHz.

The high frequency and low frequency power inputs during silicon nitride film deposition will vary depending on the type of PECVD chamber used. For example, when the films are deposited in an Applied Materials' PRODUCER® PECVD chamber (which is capable of processing a 200-mm diameter substrate wafer) or equivalent, the high frequency power is produced using an RF power input within the range of about 10 W to about 200 W; more typically, within the range of about 30 W to about 100 W; and beneficial results have been obtained within the range of about 30 W to about 80 W. The low frequency power is produced using an RF power input within the range of about 0 W to about 100 W; more typically, within the range of about 10 W to about 50 W; and beneficial results have been obtained within the range of about 10 W to about 40 W.

When the films are deposited in an Applied Materials' PRODUCER® SE™ PECVD chamber (which is capable of processing a 300-mm diameter substrate wafer), the high frequency power is produced using an RF power input within the range within the range of about 10 W to about 200 W; more typically, within the range of about 50 W to 200 W; and beneficial results have been obtained within the range of about 75 W to about 150 W. The low frequency power is generated using an RF power input within the range of about 0 W to about 100 W; more typically, within the range of about 10 W to about 100 W; and beneficial results have been obtained within the range of about 10 W to about 60 W.

In both instances, for the 200-mm diameter wafer and the 300-mm diameter wafer, the power from a low frequency generator assembly is mixed with the power from a high frequence generator assembly prior to application of the plasma generation power to the process chamber. The benefit of using a 100 W low frequency generator is that a high voltage to wattage (V/W) resolution is achieved. A 1000 W low frequency generator would typically provide a V/W ratio of about 0.01 V/W, where the 100 W generator would typically provide a ratio of about 0.10 V/W, for the apparatus referenced above. This permits a careful control over the amount of wattage applied to the plasma via adjustment of the low frequency input, since the output from the low frequency generator is much less susceptible to noise (due to a higher voltage) than the output from the high frequency generator. A power sensor is located right at the output from the mixed power supply to provide actual delivered power feedback to the controller with minimal delay. One skilled in the art may adjust the wattage for similar apparatus and other size substrates.

Regardless of which type of deposition chamber is used, the low frequency power input source is preferably capable of being adjusted in increments of 0.1 W, which allows for unprecedented control over stress produced in the depositing film, providing enhanced stress tunability. Changing the low frequency power by ±0.1 W typically results in a ±3 MPa change in the deposited film stress. This degree of control over the stress of the depositing film allows the deposition of silicon nitride films tuned to have a particular stress with great reproducibility and repeatability.

The deposition source gas typically includes about 0.1 to about 5 volume % SiH₄; about 10 to about 50 volume % NH₃; and about 40 to about 90 volume % N₂. More typically, the deposition source gas includes about 0.3 to about 3.5 volume % SiH₄; about 12 to about 25 volume % NH₃; and about 50 to about 75 volume % N₂.

If a high compressive stress film is desired, helium is typically used in place of N₂. To achieve a high compressive stress film, plasma instability occurs at low process pressure. Helium can be more easily ionized and generates a more stable plasma than N₂. In this case, the deposition source gas typically includes about 3 to about 6 volume % SiH₄; about 45 to about 65 volume % NH₃; and about 25 to about 45 volume % He. More typically, the deposition source gas includes about 4 to about 5 volume % SiH₄; about 50 to about 60 volume % NH₃; and about 30 to about 40 volume % He.

The flow rates of the constituent gases will vary depending on the type of PECVD chamber used for depositing the silicon nitride film. Flow rates of each of the constituent gases are typically higher when a larger chamber is used.

In prior art methods, which utilized multi-step deposition processes to produce films having a thickness of 1400 Å or greater, in some instances, film deposition was via a multi-chamber, multi-step deposition process. In the alternative, a single process chamber having a series of deposition stations, typically seven deposition stations, has been used. As a result of the multi-step deposition process, interfacial regions are created within the film for each deposition step. For thinner films such as those of the present invention, film quality is compromised when multi-step deposition is used, because the interfaces between the film sub-layers can contribute to film degradation, resulting in poor device performance or device failure. Deposition of films in a single deposition step inherently produces higher quality, homogeneous films, because there are no sub-layers and, hence, no interfaces which could contribute to film degradation.

The single-layer, homogeneous films of the present invention are deposited at a substrate temperature within the range of about 375° C. to about 525° C.; typically, about 375° C. to about 455° C. Deposition of stress-tuned silicon nitride films at such low temperatures prevents damage to underlying substrate layers and devices which are already present in the substrate. In the formation of a transistor, following the deposition of the silicon nitride layer, there are typically no device formation steps which require substrate temperatures in excess of 550° C.

The present invention enables deposition of a stress-tuned, single-layer silicon nitride film, where the film has a thickness within the range of about 300 Å to about 1000 Å, and where the film is tuned to have a stress within the range of about −1.4 GPa (compressive) to about +1.5 GPa (tensile). If a compressive film is required, the film stress can be tuned to be within the range of about −1.4 GPa to about 0 MPa compressive. If a tensile film is required, the film stress can be tuned to be within the range of about 0 MPa to about +1.5 GPa; typically, about +800 MPa to about +1.5 GPa.

In terms of application for the silicon nitride films produced by the present method, compressive films can be used to improve hole carrier mobilities in semiconductor devices, and particularly in transistor structures (as discussed in more detail subsequently herein). The stress present in a silicon nitride film may be used to increase or decrease the etch rate (particularly wet etch rate) of silicon nitride films which are used as a barrier layer within a semiconductor device. These application descriptions are not intended to limit the scope of the application for the silicon nitride films of the present invention, but merely provide examples for one of skill in the art.

Also disclosed herein is a PECVD chamber which is capable of depositing a film layer having a thickness of at least 100 Å (typically, within the application thickness range of about 300 Å to about 1000 Å) in a single deposition step. The chamber provides an average reactant residence time of at least 9 seconds; typically, within the range of about 15 seconds to about 100 seconds. The chamber is capable of being operated at a heater temperature which will provide a substrate temperature having a nominal value within the range of about 375° C. to about 525° C. The chamber is capable of being operated over a pressure range from about 2 Torr to about 15 Torr.

The PECVD chamber typically includes a high frequency power input source operating at a frequency within the range of about 13 MHz to about 14 MHz, and a low frequency power input source operating at a frequency within the range of about 300 kHz to about 400 kHz. When the PECVD chamber is an Applied Materials' PRODUCER® PECVD chamber (which is capable of processing a 200-mm diameter substrate wafer) or equivalent, the high frequency power input source typically utilizes an RF power within the range of about 10 W to about 200 W; more typically, within the range of about 30 W to about 100 W; and beneficial results have been obtained within the range of about 30 W to about 80 W. The low frequency power input source typically utilizes an RF power within the range of about 0 W to about 100 W; more typically, within the range of about 10 W to about 50 W; and beneficial results have been obtained within the range of about 10 W to about 40 W.

When the PECVD chamber is an Applied Materials' PRODUCER® SE™ PECVD chamber (which is capable of processing a 300-mm diameter substrate wafer) or equivalent, the high frequency power input source typically utilizes an RF power within the range of about 10 W to about 200 W; more typically, within the range of about 50 W to 200 W; and beneficial results have been obtained within the range of about 75 W to about 150 W. The low frequency power input source typically utilizes an RF power within the range of about 0 W to about 100 W; more typically, within the range of about 10 W to about 100 W; and beneficial results have been obtained within the range of about 10 W to about 60 W. One skilled in the art may adjust the wattage for similar apparatus and other size substrates.

Regardless of which type of deposition chamber is used, it is particularly advantageous when a power input source is capable of being adjusted in increments of about 0.1 W or less.

### BRIEF DESCRIPTION OF THE DRAWINGS

FIG. 1A shows a typical starting structure 100 for preparing a transistor. The structure includes the following layers: heavily doped substrate 102, including source 104 and drain 106 regions; gate dielectric layer 108; polysilicon layer 110; silicon oxide liner 112; carbon-doped silicon nitride spacers 114; and nitrogen silicide layer 116.

FIG. 1B shows structure 100 after deposition of a conformal silicon nitride layer 118. According to the present method, the stress of silicon nitride layer 118 can be tuned to have a nominal value within the range of −1.4 GPa (compressive) to about +1.5 GPa (tensile), by setting various process parameters within specified ranges.

FIG. 1C shows structure 100 after deposition of a conformal pre-metal dielectric layer 120 overlying inventive silicon nitride layer 118.

FIG. 2 is a graph 200 showing the refractive index 202 and wet etch rate 204 (in 100:1H₂O: HF) as a function of the film stress 206 of the film stress 206 of silicon nitride films deposited according to the present method.

FIG. 3A is a top view schematic of a multi-chamber processing system of the kind which may be used to carry out the method described herein, a PRODUCER®, available from Applied Materials, Inc. (Santa Clara, Calif.). The PRODUCER® processing system is capable of processing a 200-mm diameter substrate wafer.

FIG. 3B is a schematic showing high frequency (HF) power input 350 and low frequency (LF) power input 360, which are mixed at mixer 358 prior to application to a PRODUCER® or PRODUCER® SE™ PECVD chamber 340.

FIG. 4A shows a block diagram 400 which illustrates the stress (on scale 402) of a silicon nitride film having a thickness of about 2500 Å as a function of the N—H peak position on an FTIR curve (on scale 404).

FIG. 4B shows a block diagram 400 which illustrates the stress (on scale 422) of the silicon nitride film shown in FIG. 4A, but with the stress as a function of the integrated N—H area under the FTIR curve (on scale 424).

FIG. 5A shows a block diagram 500 which illustrates the stress (on scale 502) of a silicon nitride film having a thickness of about 2500 Å as a function of the Si—H peak position on an FTIR curve (on scale 504).

FIG. 5B shows a block diagram 500 which illustrates the stress (on scale 522) of the silicon nitride film shown in FIG. 5A, but with the stress as a function of the integrated Si—H area under the FTIR curve (on scale 524).

FIG. 6A shows a block diagram 600 which illustrates the stress (on scale 602) of a silicon nitride film having a thickness of about 2500 Å as a function of the Si—N peak position on an FTIR curve (on scale 604).

FIG. 6B shows a block diagram 600 which illustrates the stress (on scale 622) of the silicon nitride film shown in FIG. 6A, but with the stress as a function of the integrated Si—N area under the FTIR curve (on scale 624).

FIG. 7A is a graph 700 showing the stress 702 of silicon nitride films having a thickness of either 600 Å or 3000 Å, which were deposited according to the present method. The films were deposited under different deposition conditions to provide films having a range of compressive stress values.

FIG. 7B is a graph 710 showing the stress 712 of silicon nitride films having a thickness of either 600 Å or 3000 Å, which were deposited according to the present method. The films were deposited under different deposition conditions to provide films having a range of tensile stress values.

FIG. 8A is a graph 800 showing the tensile stress 802 of silicon nitride films deposited according to the present method, as a function of the SiH₄ flow 804 during film deposition.

FIG. 8B is a graph 810 showing the deposition rate 812 of silicon nitride films deposited according to the present method, as a function of the SiH₄ flow 814 during film deposition.

FIG. 8C is a graph 820 showing the refractive index 822 of silicon nitride films deposited according to the present method, as a function of the SiH₄ flow 824 during film deposition.

FIG. 9 is a graph 900 showing the tensile stress 902 of silicon nitride films deposited according to the present method, as a function of the NH₃ flow 904 during film deposition.

FIG. 10A is a graph 1000 showing the tensile stress 1002 of silicon nitride films deposited according to the present method, as a function of the N₂ flow 1004 during film deposition.

FIG. 10B is a graph 1010 showing the refractive index 1012 of silicon nitride films deposited according to the present method, as a function of the N₂ flow 1014 during film deposition.

FIG. 11A is a graph 1100 showing the tensile stress 1102 of silicon nitride films deposited according to the present method, as a function of the low frequency power input 1104 applied during film deposition.

FIG. 11B is a graph 1110 showing the deposition rate 1112 of silicon nitride films deposited according to the present method, as a function of the low frequency power input 1114 applied during film deposition.

FIG. 11C is a graph 1100 showing the refractive index 1122 of silicon nitride films deposited according to the present method, as a function of the low frequency power input 1124 applied during film deposition.

FIG. 12A is a graph 1200 showing the tensile stress 1202 of silicon nitride films deposited according to the present method, as a function of the process chamber pressure 1204 during film deposition.

FIG. 12B is a graph 1210 showing the deposition rate 1212 of silicon nitride films deposited according to the present method, as a function of the process chamber pressure 1214 during film deposition.

FIG. 13A is a graph 1300 showing the tensile stress 1302 of silicon nitride films deposited according to the present method, as a function of the spacing 1304 between the faceplate and the heater within the processing chamber.

FIG. 13B is a graph 1310 showing the deposition rate 1312 of silicon nitride films deposited according to the present method, as a function of the spacing 1314 between the faceplate and the heater within the processing chamber.

FIG. 14A is a graph 1400 showing the tensile stress 1402 of silicon nitride films deposited according to the present method, as a function of the heater temperature 1404 during film deposition. (The substrate temperature is typically about 25° C. less than the heater temperature.)

FIG. 14B is a graph 1410 showing the refractive index 1412 and deposition rate 1414 of silicon nitride films deposited according to the present method, as a function of the heater temperature 1416 during film deposition.

FIG. 15 is a graph 1500 showing the % hydrogen content 1502 as a function of the film stress 1504 of silicon nitride films deposited according to the present method.

### DETAILED DESCRIPTION OF THE INVENTION

Disclosed herein is a method of tuning the stress of a single-layer, homogeneous silicon nitride film over a broad range previously unattainable. The exemplary processing conditions for performing various embodiments of the method of the invention set forth below are not intended to limit the scope of the inventive concept provided herein.

As a preface to the detailed description, it should be noted that, as used in this specification and the appended claims, the singular forms “a”, “an”, and “the” include plural referents, unless the context clearly dictates otherwise.

I. An Apparatus for Practicing the Invention

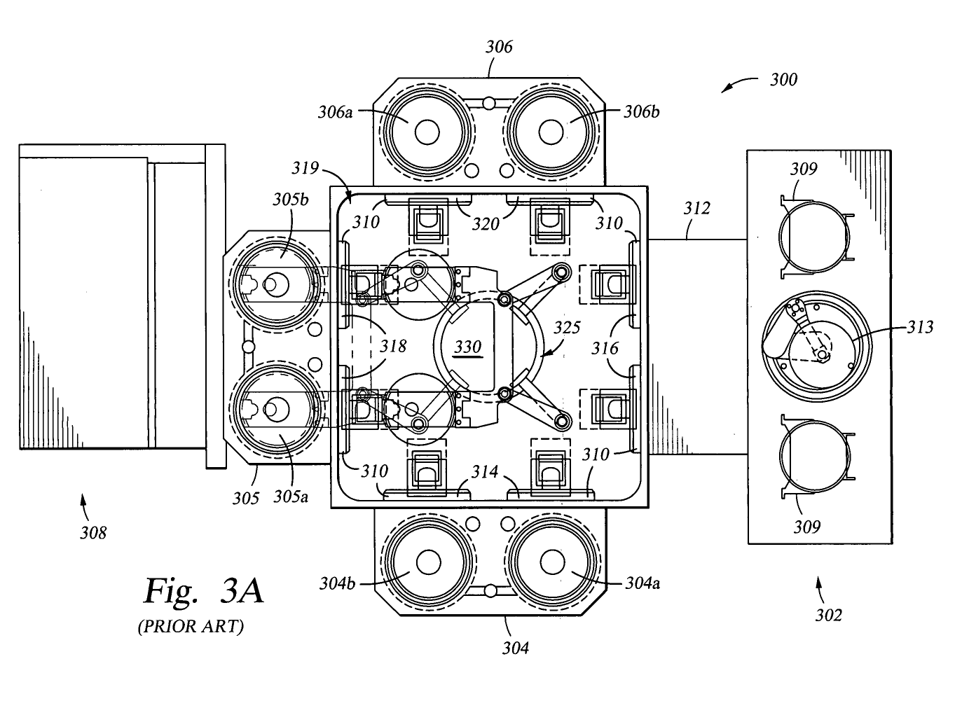

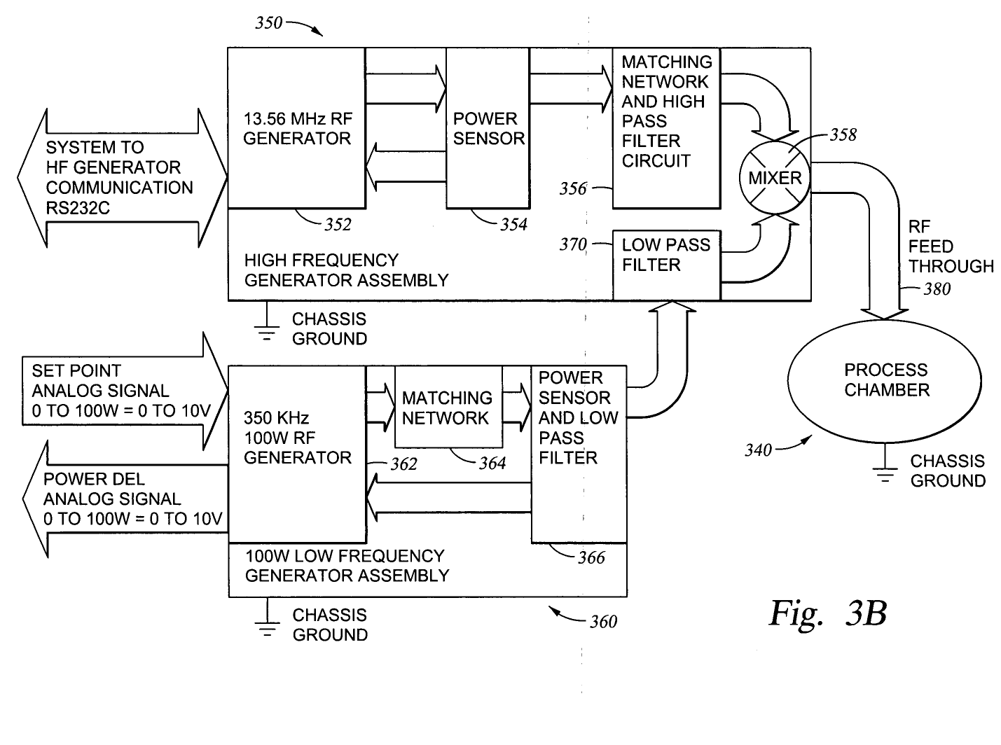

FIG. 3A is a top view schematic of a multi-chamber processing system of the kind which may be used to carry out the method described herein, a PRODUCER®, available from Applied Materials, Inc. (Santa Clara, Calif.). The PRODUCER®processing platform is used to support a fully automated substrate processing system employing a single-substrate, multi-chambered design. This system also includes computerized process control (not shown) including a hierarchal process control system. An advantage of the PRODUCER® processing system is that it permits the use of wet processing as well as dry processing, and enables high vacuum, low vacuum, and atmospheric processes.

The PRODUCER®processing system 300 shown in FIG. 3A includes a front end staging area 302, which includes substrate-holding cassettes 309 and a front end substrate handler (i.e., robot) 313. Substrates (not shown) pass from the front end staging area 302 through a load-lock chamber 312 into transfer chamber 319. Within transfer chamber 319 are various passages 310 which include one or more slit valve openings and slit valves. Passages 310 enable communication between the transfer chamber 319 and other processing chambers, permitting staged vacuum within system 300. For example, with reference to specific passages, a substrate may pass from load-lock chamber 312 into transfer chamber 319 through passages 316; may pass from transfer chamber 319 into process chamber region 304 into either process chamber 304a or 304b through one of the passageways 314; may pass from transfer chamber 319 into process chamber region 305 into either process chamber 305a or 305b through one of the passageways 318; and may pass from transfer chamber 319 into process chamber region 306, into either process chamber 306a or 306b, through one of the passageways 320. Process chamber regions 304, 305, and 306 may each be under a different pressure condition. Substrate handler 330 facilitates substrate movement from within a central passage 325. Toward the back end of processing system 300 is a housing 308 which houses support utilities (not shown).

The PRODUCER® processing system is capable of processing 200-mm diameter substrate wafers. The PRODUCER® SE™ processing system (also available from Applied Materials, Inc., Santa Clara, Calif.) is a related processing system which is capable of processing 300-mm diameter substrate wafers. The PRODUCER® SE™ 300-mm processing system is similar in design to the PRODUCER® 200-mm processing system shown in FIG. 3A. The PRODUCER® SE™ processing system includes several additional features. For instance, the PRODUCER® SE™ processing system includes two robots for handling two substrates simultaneously (as compared to the single substrate-handling robot 313 shown in FIG. 3A). The load-lock chamber 312 of the PRODUCER® SE™ processing system also contains a heater for pre-heating the substrate wafers (not shown) prior to loading the substrate wafers into their respective processing chambers. Pre-heating the substrate prior to loading the substrate into the processing chamber means that the substrate requires less heating time in the processing chamber before processing of the substrate can begin. This results in decreased processing time and increased substrate throughput.

To carry out the method described herein, the processing chamber modules which would be incorporated into a PRODUCER® or PRODUCER® SE™ processing system would include, for example and not by way of limitation, a 200-mm PRODUCER® or 300-mm PRODUCER® SE™ plasma-enhanced chemical vapor deposition (PECVD) chamber having dual power input sources operating within different frequency ranges (“dual frequency power”). A high frequency power input source typically operates at a frequency within the range of about 13MHz to about 14 MHz, produced using an RF power input within the range of about 0 W to about 200 W. A low frequency power input source typically operates at a frequency within the range of about 300 kHz to about 400 kHz, produced using an RF power input ranging from about 0 W to about 100 W. The low frequency power input source is preferably capable of being adjusted in increments of about 0.1 W or less, which allows for unprecedented control over stress produced in the depositing film, providing enhanced stress tunability. One skilled in the art to which the invention belongs will know how to adjust the power inputs to obtain a similar plasma density in a similar apparatus. Other factors which have a significant impact on the stress produced in the depositing film include process chamber pressure and SiH₄ flow to the chamber during film deposition.

FIG. 3B is a schematic showing power input to a 200-mm PRODUCER® or 300-mm PRODUCER® SE™ PECVD chamber 340. The high frequency generator assembly 350 includes a 13.56 MHz RF generator 352, power sensor 354, and matching network and high pass filter circuit 356. The maximum power output for the high frequency generator for the 200-mm PRODUCER® is 2000 W; the maximum power output for the high frequency generator for the 300-mm PRODUCER® is 3000 W. The high frequency generator assembly also includes a mixer 358 and a low pass filter 370 into which power from the low frequency generator enters.

The low frequency generator assembly 360 includes a 350 kHz 100 W RF generator 362, matching network 364, and power sensor and low pass filter 366. The low frequency power passes into the high frequency generator assembly through the low pass filter 370, and then to mixer 358, where the high frequency and low frequency powers are mixed prior to passing to the PECVD process chamber 340 through RF feedthrough 380.

The benefit of using a 100 W low frequency generator is that a high voltage to wattage (V/W) resolution is achieved. A 1000 W low frequency generator would typically provide a V/W ratio of about 0.01 V/W, where the 100 W generator would typically provide a ratio of about 0.10 V/W, for the apparatus referenced above. This permits a careful control over the amount of wattage applied to the plasma via adjustment of the low frequency input, since the output from the low frequency generator is much less susceptible to noise (due to a higher voltage) than the output from the high frequency generator. A power sensor is located right at the output from the mixed power supply to provide actual delivered power feedback to the controller with minimal delay.

The substrate support pedestals (not shown) of the PRODUCER® and PRODUCER® SE™ PECVD chambers are grounded, resulting in a self-bias on the substrate of about −10 V. Alternatively, a PECVD chamber which includes means (not shown) for biasing the substrate can be used to perform the present silicon nitride film deposition method. Typically, as the bias power to the substrate is increased, ion bombardment of the depositing film increases, resulting in a more dense film having higher compressive stress. Therefore, if a silicon nitride film having a high compressive stress is desired, it is advisable to utilize a process chamber which includes means for biasing the substrate during film deposition.

The PECVD chamber 340 should have the capability of depositing a film layer having a thickness of at least 100 Å (typically, within the range of about 300 Å to about 1000 Å) in a single deposition step. A residence time for the reactant species of at least 9 seconds, and typically, within the range of about 15 seconds to about 60 seconds, is required to deposit a 200-700 Å thick film. In order to deposit silicon nitride films according to the method of the invention disclosed herein, the chamber must be capable of operating at a heater temperature which provides a substrate temperature having a nominal value within a range of about 375° C. to about 525° C., and over a pressure ranging from about 2 Torr to about 15 Torr.

Deposition of films in a single step in a single chamber has advantages over prior art methods which utilized multi-chamber or single-chamber, multi-step deposition processes. In the prior art, the films deposited were typically about 10,000 Å thick, and the film was deposited in seven steps, with each individual layer having a thickness of approximately 1400 Å. Film quality is compromised when multi-step deposition is used, because the interfaces between the film sub-layers can contribute to film degradation, resulting in poor device performance or device failure. By tuning the stress of the silicon nitride film as described herein, it is possible to use a thinner silicon nitride film. Deposition of thinner films, having a thickness ranging from about 300 Å to about 1000 Å, in a single deposition step as described in the present invention inherently produces higher quality films, because there are no surface interfaces which could contribute to film degradation.

II. Method of Tuning the Stress of a Silicon Nitride Film

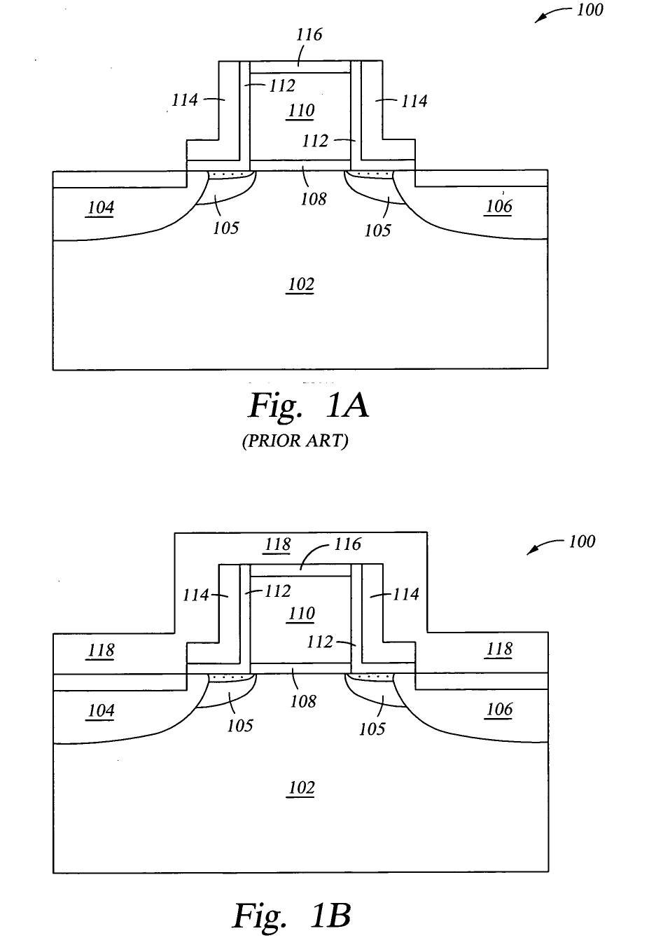

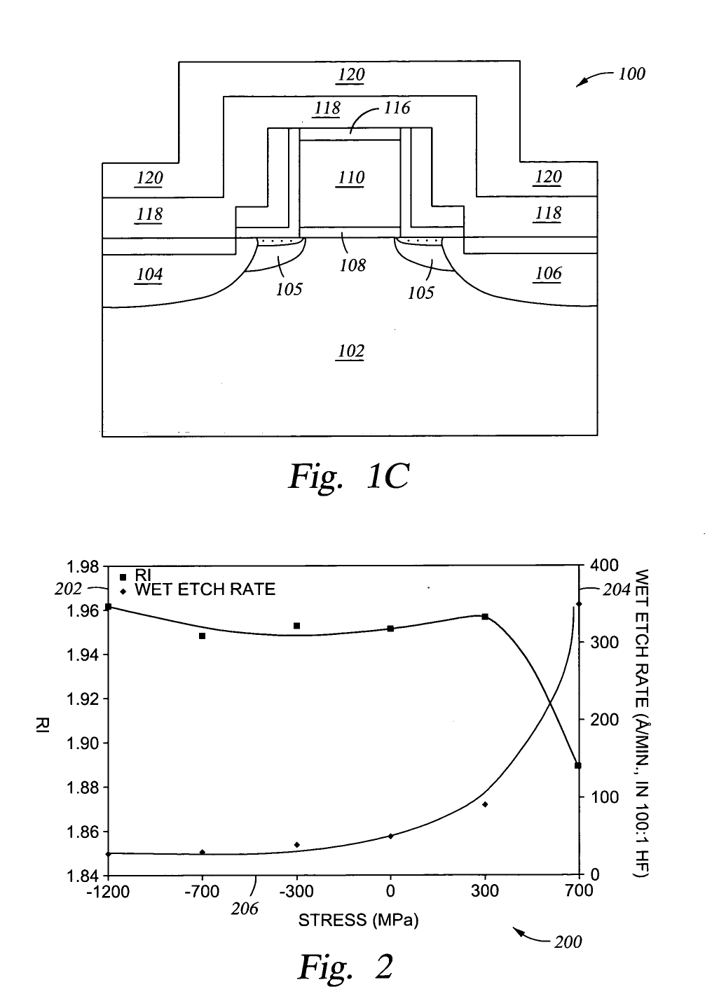

FIG. 1A shows a typical starting structure 100 for preparing a transistor. The structure includes the following layers: heavily doped substrate 102, including source 104 and drain 106 regions; medium-doped drain (MDD)/halo and retrograde well areas 105; gate dielectric layer 108 (which is typically silicon oxide); polysilicon layer 110; silicon oxide liner 112; carbon-doped silicon nitride spacers 114; and nitrogen silicide layer 116. The structure 100 can be prepared using conventional deposition and etch techniques known in the art of semiconductor processing.

The present method comprises depositing a stress-tuned silicon nitride film from SiH₄, NH₃, and N₂ using plasma-enhanced chemical vapor deposition (PECVD) techniques. The deposition source gas typically includes about 0.1 to about 5 volume % SiH₄; about 10 to about 50 volume % NH₃; and about 40 to about 90 volume % N₂. More typically, the deposition source gas includes about 0.3 to about 3.5 volume % SiH₄; about 12 to about 25 volume % NH₃; and about 50 to about 75 volume % N₂.

If a high compressive stress film is desired, helium is typically used in place of N₂. To achieve a high compressive stress film, plasma instability occurs at low process pressure. Helium can be more easily ionized and generates a more stable plasma than N₂. In this case, the deposition source gas typically includes about 3 to about 6 volume % SiH₄; about 45 to about 65 volume % NH₃; and about 25 to about 45 volume % He. More typically, the deposition source gas includes about 4 to about 5 volume % SiH₄; about 50 to about 60 volume % NH₃; and about 30 to about 40 volume % He.

The silicon nitride film is typically deposited in a single deposition step to a thickness within a range of about 300 Å to about 1000 Å, although thicker films may be deposited if desired. Film deposition is performed using an apparatus which has multiple (typically dual) power input sources operating within different frequency ranges, as described previously with reference to the apparatus. A high frequency power input source typically operates at a frequency within the range of about 13 MHz to about 14 MHz. A low frequency power input source typically operates at a frequency within the range of about 300 kHz to about 400 kHz.

The stress in the silicon nitride film can be tuned to be within the range of about −1.4 GPa (compressive) to about +1.5 GPa (tensile), in accordance with the data shown in Table IV, below. If a compressive film is required, the film stress can be tuned to be within the range of about −1.4 GPa to about 0 MPa. If a tensile film is required, the film stress can be tuned to be within the range of about 0 MPa to about +1.5 GPa; typically, about +800 MPa to about +1.5 GPa, in accordance with the data shown in Table V, below.

Application of a high tensile stress film to an nMOS transistor structure can improve nMOS transistor structure performance, but does not typically degrade pMOS transistor structure performance. Application of a high compressive stress film to a pMOS transistor structure can improve pMOS transistor structure performance, but may also degrade NMOS transistor structure performance. Therefore, application of a high tensile stress film to improve electron mobility is typically more desirable for transistor applications.

Silicon nitride film deposition conditions for the 200-mm PRODUCER® and the 300-mm PRODUCER® SE™ PECVD chamber are slightly different. For example, the flow rates of each of the constituent gases are necessarily higher in the 300-mm chamber. Also, the high frequency and low frequency power inputs to the 200-mm and 300-mm chambers differ. The process chamber pressure during film deposition will also vary depending on the type of chamber used, with the larger chamber allowing use of higher pressures (up to about 10-15 Torr). One skilled in the art may adjust the wattage and other processing conditions for similar apparatus and other size substrates.

Table I, below, presents typical process conditions for PECVD deposition of silicon nitride films in a 200-mm PRODUCER® PECVD chamber (or equivalent) according to the present method.

TABLE I
Typical Process Conditions for Deposition of Silicon Nitride Films
in a 200-mm PECVD Chamber

| | | | Optimum |
|---|---|---|---|
| | Range of Process | Typical Process | Known Process |
| Process Parameter | Conditions | Conditions | Conditions |
| SiH₄ Flow Rate (sccm) | 25-150 | 30-120 | 30-120 |
| NH₃ Flow Rate (sccm) | 300-4000 | 400-3600 | 400-3600 |
| N₂ Flow Rate (sccm) | 500-2000 | 750-1500 | 800-1200 |
| He Flow Rate (sccm)* | 1000-3000 | 1500-2500 | 1800-2200 |
| Total Gas Flow Rate (sccm) | 825-6150 | 1430-4720 | 1430-4720 |
| High Frequency RF Power (W) | 10-200 | 30-100 | 30-80 |
| (at 13.56 MHz frequency) | | | |
| Low Frequency RF Power (W) | 0-100 | 10-50 | 10-40 |
| (at 350 kHz frequency) | | | |
| Process Chamber Pressure (Torr) | 2-10 | 2-6 | 2-6 |
| Substrate Temperature (° C.) | 350-525 | 375-455 | 375-425 |
| Heater Temperature (° C.) | 375-550 | 400-480 | 400-450 |
| Film Thickness (Å) | 300-1000 | 300-1000 | 300-1000 |

*Helium used instead of N₂ for high compressive stress films only.

Table II, below, presents typical process conditions for PECVD deposition of silicon nitride films in a 300-mm PRODUCER® SE™ PECVD chamber (or equivalent) according to the present method.

TABLE II
Typical Process Conditions for Deposition of Silicon Nitride Films
in a 300-mm PECVD Chamber

| | | | Optimum |
|---|---|---|---|
| | Range of Process | Typical Process | Known Process |
| Process Parameter | Conditions | Conditions | Conditions |
| SiH₄ Flow Rate (sccm) | 40-350 | 50-300 | 75-240 |
| NH₃ Flow Rate (sccm) | 1000-5000 | 1600-4800 | 1600-3200 |
| N₂ Flow Rate (sccm) | 2000-20,000 | 4000-10,000 | 8000-10,000 |
| He Flow Rate (sccm)* | 2000-5000 | 3000-4500 | 3800-4200 |
| Total Gas Flow Rate (sccm) | 3040-25,350 | 5650-15,100 | 11,675-13,440 |
| High Frequency RF Power (W) | 10-200 | 50-200 | 75-150 |
| (at 13.56 MHz frequency) | | | |
| Low Frequency RF Power (W) | 0-100 | 10-100 | 10-60 |
| (at 350 kHz frequency) | | | |
| Process Chamber Pressure (Torr) | 2-15 | 2-10 | 2-10 |
| Substrate Temperature (° C.) | 350-525 | 375-455 | 375-425 |
| Heater Temperature (° C.) | 375-550 | 400-480 | 400-450 |
| Film Thickness (Å) | 300-1000 | 300-1000 | 300-1000 |

*Helium used instead of N₂ for high compressive stress films only.

The substrate support pedestals of the PRODUCER® and PRODUCER® SE™ PECVD chambers are grounded, resulting in a self-bias on the substrate of about −10 V. Alternatively, a PECVD chamber which includes means for biasing the substrate can be used to perform the present silicon nitride film deposition method. Typically, as the bias power to the substrate is increased, ion bombardment of the depositing film increases, resulting in a more dense film having higher compressive stress. Therefore, if a silicon nitride film having a high compressive stress is desired, it is advisable to utilize a process chamber which includes means for biasing the substrate during film deposition.

FIG. 1B shows structure 100 after deposition of a conformal layer 118 of silicon nitride according to the present method, and FIG. 1C shows structure 100 after deposition of a conformal pre-metal dielectric layer 120 overlying silicon nitride layer 118. Pre-metal dielectric layer 120 can be deposited using conventional deposition techniques known in the art.

In addition to being deposited as part of a structure to control electron mobility, as shown in FIG. 1B, a stress-tuned silicon nitride film can be deposited for other purposes in various steps in the fabrication process, for example (and not by way of limitation), to provide an etch stop layer, to provide offset spacers, and to provide trench isolation, as well as to enhance channel mobility in various portions of the device structure.

The stress present in a silicon nitride film may be used to increase or decrease the etch rate (particularly wet etch rate) of silicon nitride films which are used as a barrier layer within a semiconductor device. FIG. 2 is a graph 200 showing the refractive index 202 and wet etch rate 204 (in 100:1H₂O: HF) as a function of the film stress 206 of the film stress 206 of silicon nitride films deposited according to the present method.

The data shown in FIG. 2 indicate that the refractive index of the silicon nitride films remained relatively constant for films having stresses within the range of −1.2 GPa (−1200 MPa) to 300 MPa. The etch rate of films increased gradually with increasing stress for films having stresses within the range of −1.2 GPa to 300 MPa. However, films having a tensile stress of 700 MPa showed a surprising decrease in refractive index to about 1.89, and a surprising increase in wet etch rate to about 350 Å/min. in a 100:1 solution of water: HF.

### III. EXAMPLES

The data in the Examples below were generated using a PRODUCERS SE™ processing system (available from Applied Materials, Inc.) to deposit the silicon nitride films.

We were able to produce a conformal silicon nitride film exhibiting a tensile stress of greater than 700 MPa and having a refractive index averaging 1.97, under the process conditions provided in Table II, below. The substrate was a 300-mm diameter silicon wafer and the uniformity of the silicon nitride film across the wafer was excellent, as indicated by the data in Table III.

TABLE III
Uniformity of Silicon Nitride Film Deposition Process

| | Left Side | |
|---|---|---|
| Process Parameter | of Substrate | Right Side of Substrate |
| SiH₄ Flow Rate (sccm) | 330 | 330 |
| NH₃ Flow Rate (sccm) | 3200 | 3200 |
| N₂ Flow Rate (sccm) | 4000 | 4000 |
| Total Gas Flow Rate (sccm) | 7530 | 7530 |
| High Frequency RF Power (W) | 100 | 100 |
| (at 13.56 MHz frequency) | | |
| Low Frequency RF Power (W) | 10 | 10 |
| (at 350 kHz frequency) | | |
| Process Chamber Pressure (Torr) | 5 | 5 |
| Temperature (° C.) | 450 | 450 |
| Spacing Between Faceplate and | 480 | 480 |
| Heater (mils) | | |
| Film Thickness (Å) | 2318 | 2404 |
| 1 σ (%) | 1.7 | 0.87 |
| Range* | 80.0 | 73.9 |
| Refractive Index | 1.9694 | 1.9867 |
| Stress (MPa) | 712.9 | 710.2 |

*Range = Thickness difference between the highest point and the lowest point on the same silicon wafer.

The data in Table III indicate that silicon nitride films can be reproducibly deposited to have a particular controlled film stress and other properties. (Films having thicknesses in the 2000 Å to 3000 Å range were deposited for evaluation purposes.)

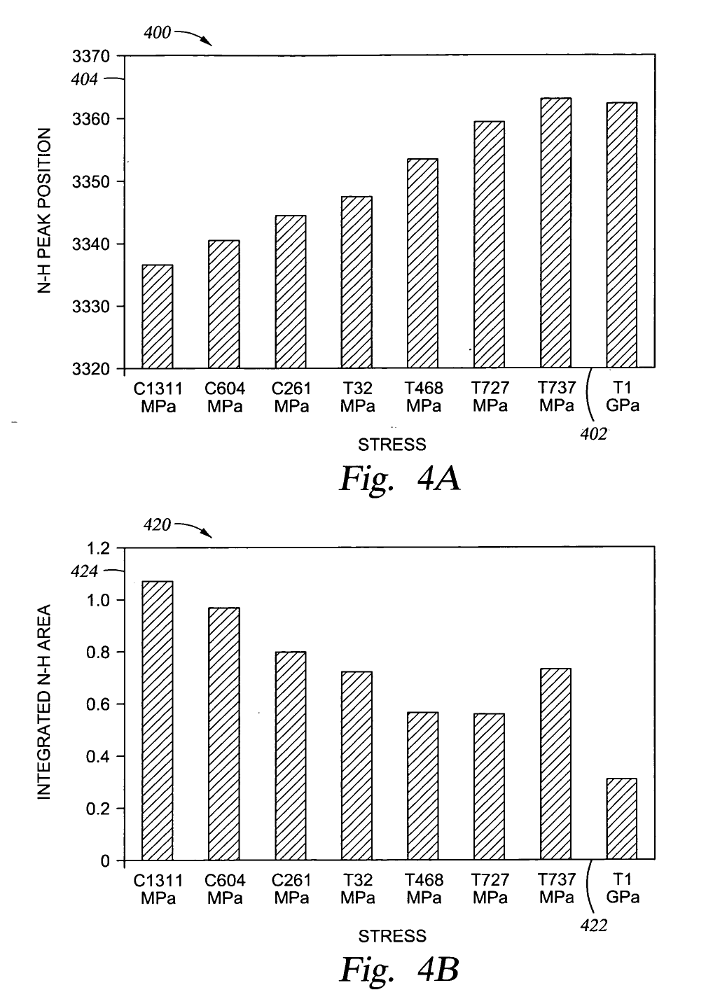

FIG. 4A shows a block diagram 400 which illustrates the stress (on scale 402) of a silicon nitride film having a thickness of about 2500 Å as a function of the N—H peak position on an FTIR curve (on scale 404). FIG. 4B shows a block diagram 400 which illustrates the stress (on scale 422) of the silicon nitride film shown in FIG. 4A, but with the stress as a function of the integrated N—H area under the FTIR curve (on scale 424).

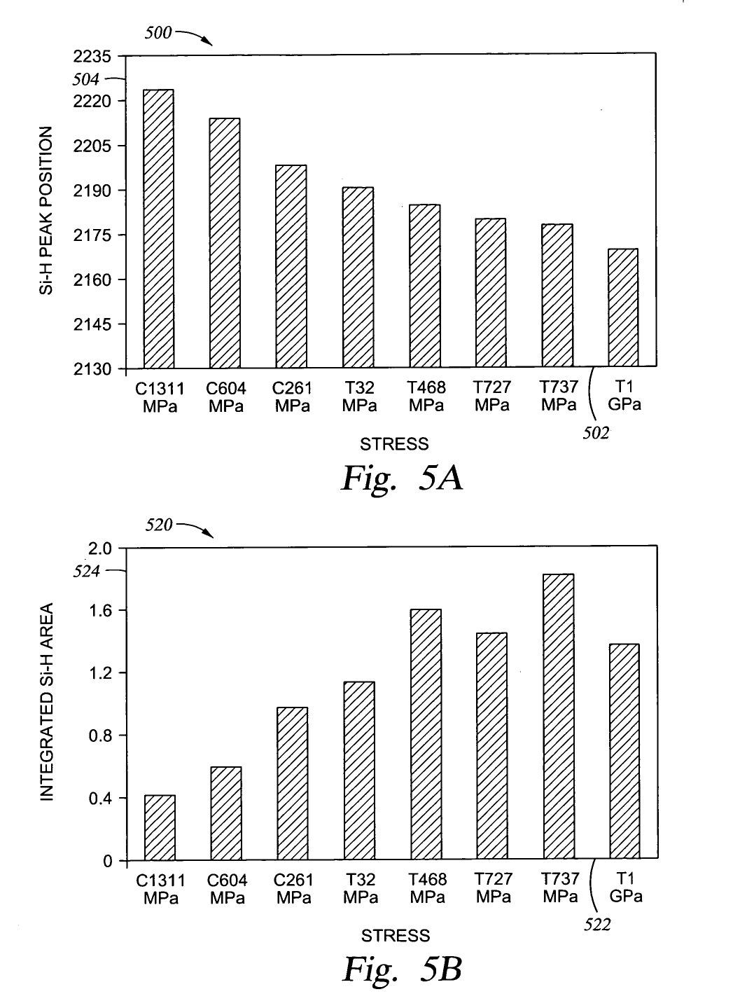

FIG. 5A shows a block diagram 500 which illustrates the stress (on scale 502) of a silicon nitride film having a thickness of about 2500 Å as a function of the Si—H peak position on an FTIR curve (on scale 504). FIG. 5B shows a block diagram 500 which illustrates the stress (on scale 522) of the silicon nitride film shown in FIG. 5A, but with the stress as a function of the integrated Si—H area under the FTIR curve (on scale 524).

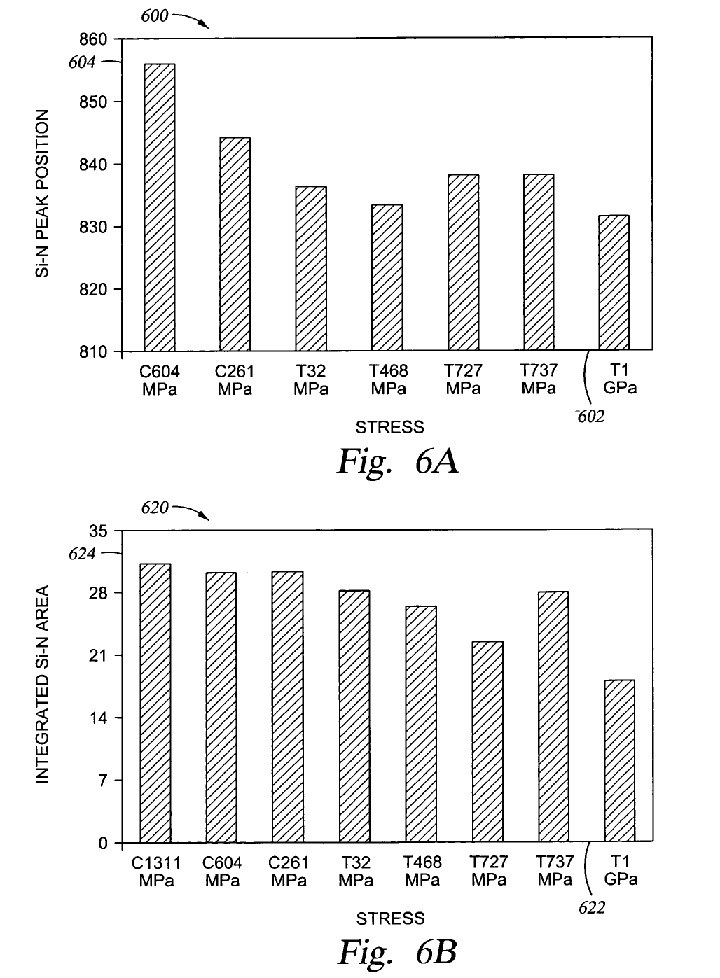

FIG. 6A shows a block diagram 600 which illustrates the stress (on scale 602) of a silicon nitride film having a thickness of about 2500 Å as a function of the Si—N peak position on an FTIR curve (on scale 604). FIG. 6B shows a block diagram 600 which illustrates the stress (on scale 622) of the silicon nitride film shown in FIG. 6A, but with the stress as a function of the integrated Si—N area under the FTIR curve (on scale 624).

Deposition conditions for the particular silicon nitride films which provided the data shown in the graphs in FIGS. 4A, 4B, 5A, 5B, 6A, and 6B are shown in Tables IV and V below. Table IV shows the deposition conditions for silicon nitride films which were deposited under conditions which provided compressive stress films. Table V shows the deposition conditions for silicon nitride films which were deposited under conditions which provided tensile stress films.

TABLE IV
Deposition Conditions for Compressive Stress Silicon Nitride Films

| Film Stress: | −1311 MPa | −604 MPa | −261 MPa |
|---|---|---|---|
| SiH₄ Flow Rate (sccm) | 45 | 30 | 120 |
| NH₃ Flow Rate (sccm) | 600 | 400 | 1600 |
| N₂ Flow Rate (sccm) | 0 | 250 | 1000 |
| He Flow Rate (sccm) | 2000 | 0 | 0 |
| Total Gas Flow Rate (sccm) | 2645 | 680 | 2720 |
| High Frequency RF Power (W) | 30 | 30 | 50 |
| (at 13.56 MHz frequency) | | | |
| Low Frequency RF Power (W) | 30 | 27 | 30 |
| (at 350 kHz frequency) | | | |
| Process Chamber Pressure (Torr) | 2.5 | 2 | 2.5 |
| Substrate Temperature (° C.) | 400 | 400 | 400 |
| Heater Temperature (° C.) | 430 | 430 | 430 |
| Film Thickness (Å) | 3100 | 3000 | 3100 |

TABLE V
Deposition Conditions for Tensile Stress Silicon Nitride Films

| | Film Stress: | | | | |
|---|---|---|---|---|---|
| | | 468 | 727 | 737 | |
| | 32 MPa | MPa | MPa | MPa | 1 GPa |
| SiH₄ Flow Rate (sccm) | 120 | 120 | 120 | 120 | 75 |
| NH₃ Flow Rate (sccm) | 1600 | 1600 | 3600 | 3600 | 3200 |
| N₂ Flow Rate (sccm) | 1000 | 1000 | 1000 | 0 | 10,000 |
| He Flow Rate (sccm) | 0 | 0 | 0 | 2000 | 0 |
| Total Gas Flow Rate (sccm) | 2720 | 2720 | 4720 | 5720 | 13,275 |
| High Frequency RF | 50 | 50 | 50 | 50 | 100 |
| Power (W) (at 13.56 | | | | | |
| MHz frequency) | | | | | |
| Low Frequency RF | 22 | 20 | 16 | 15 | 10 |
| Power (W) (at 350 | | | | | |
| kHz frequency) | | | | | |
| Process Chamber Pressure | 2.5 | 3.5 | 4.5 | 6 | 5 |
| (Torr) | | | | | |
| Substrate Temperature | 400 | 400 | 400 | 400 | 420 |
| (° C.) | | | | | |
| Heater Temperature (° C.) | 430 | 430 | 430 | 430 | 450 |
| Film Thickness (Å) | 3000 | 3100 | 3000 | 3200 | 2500 |

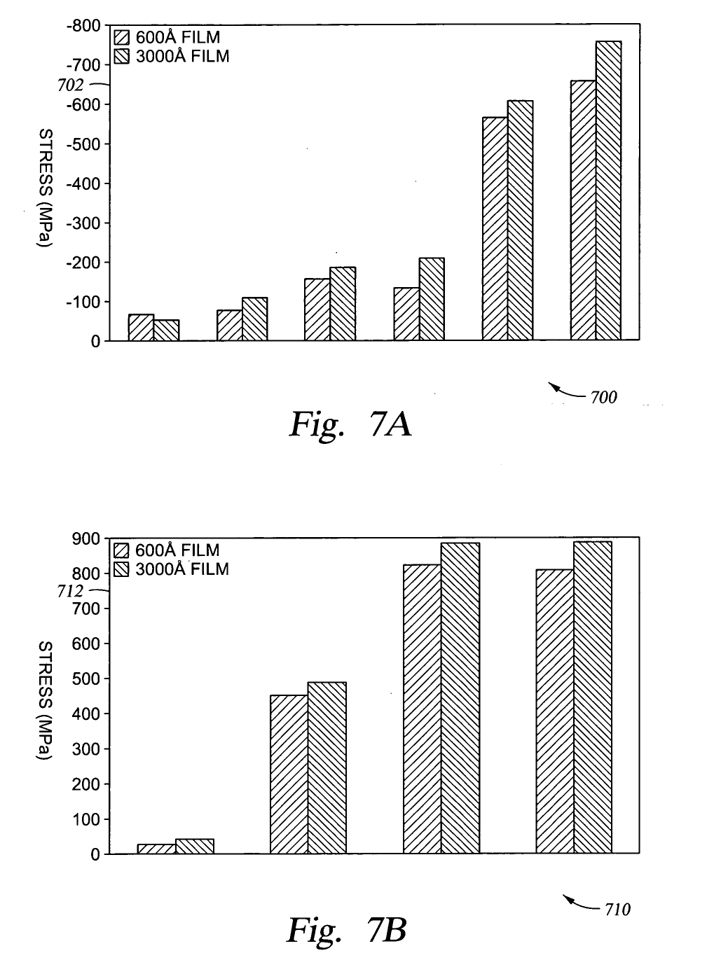

FIG. 7A is a graph 700 showing the compressive stress on scale 702 of silicon nitride films which were deposited according to the present method, where the films had thicknesses of either 600 Å or 3000 Å. The films were deposited under a variety of different deposition conditions to provide films having compressive stress values ranging from greater than −800 MPa to less than −100 MPa. The difference in film stress as a function of film thickness is minor.

FIG. 7B is a graph 710 showing the tensile stress on scale 712 of silicon nitride films which were deposited according to the present method, where the films had thicknesses of either 600 Å or 3000 Å. The films were deposited under a variety of different deposition conditions to provide films having tensile stress values ranging from less than 50 MPa to greater than 700 MPa. The difference in film stress as a function of film thickness is minor.

The data shown in FIGS. 7A and 7B show that, under the deposition conditions of the present method, film thickness does not have a significant effect on film stress, whether the films are in compressive stress or tensile stress.

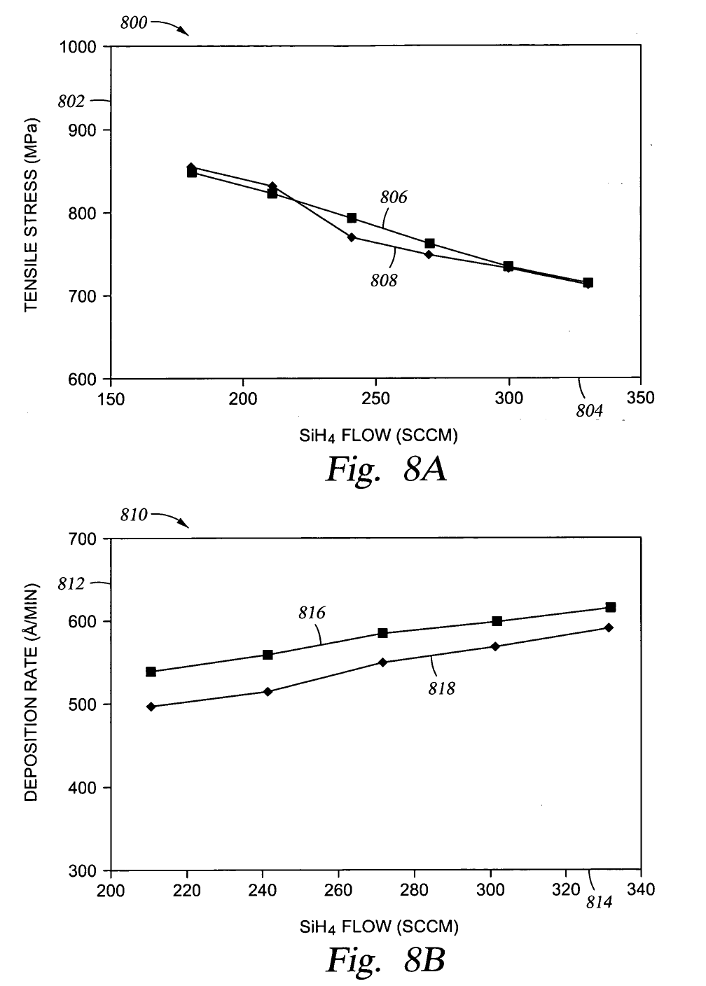

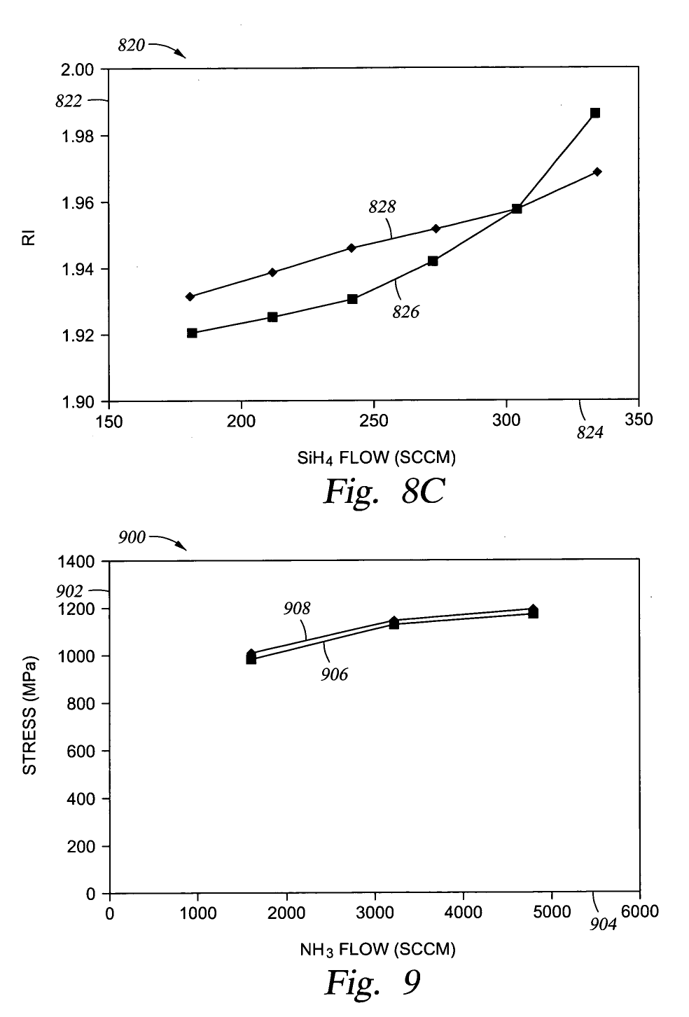

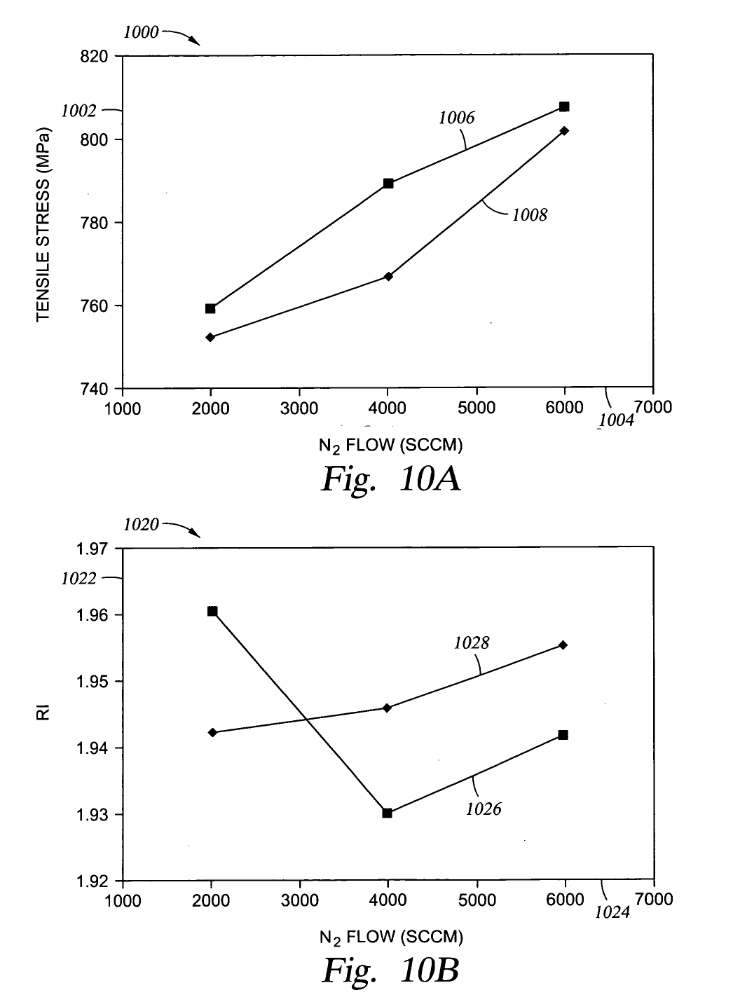

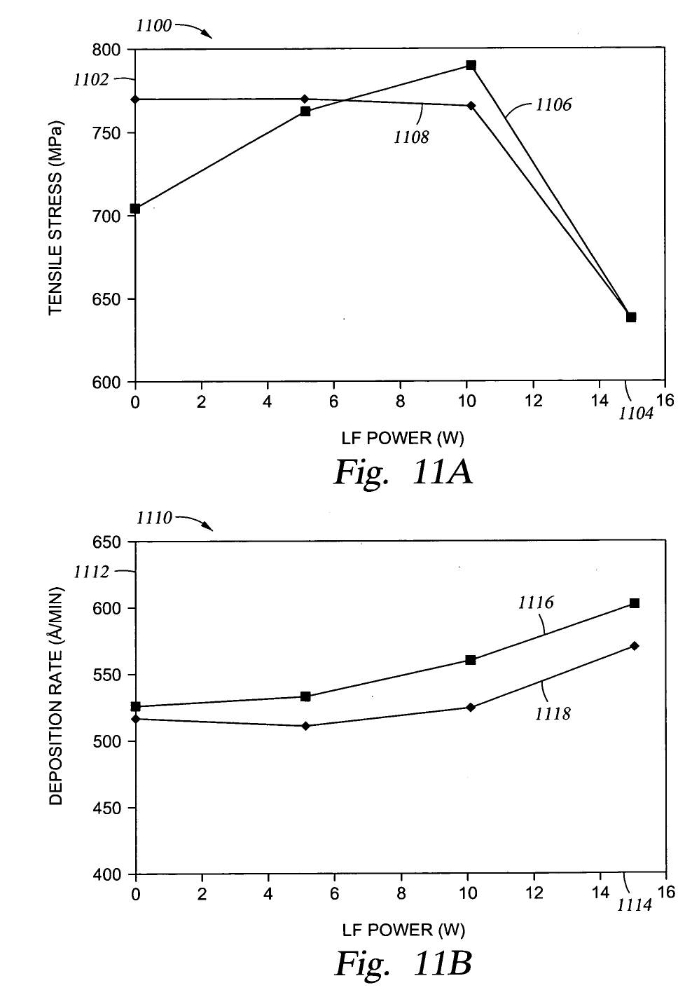

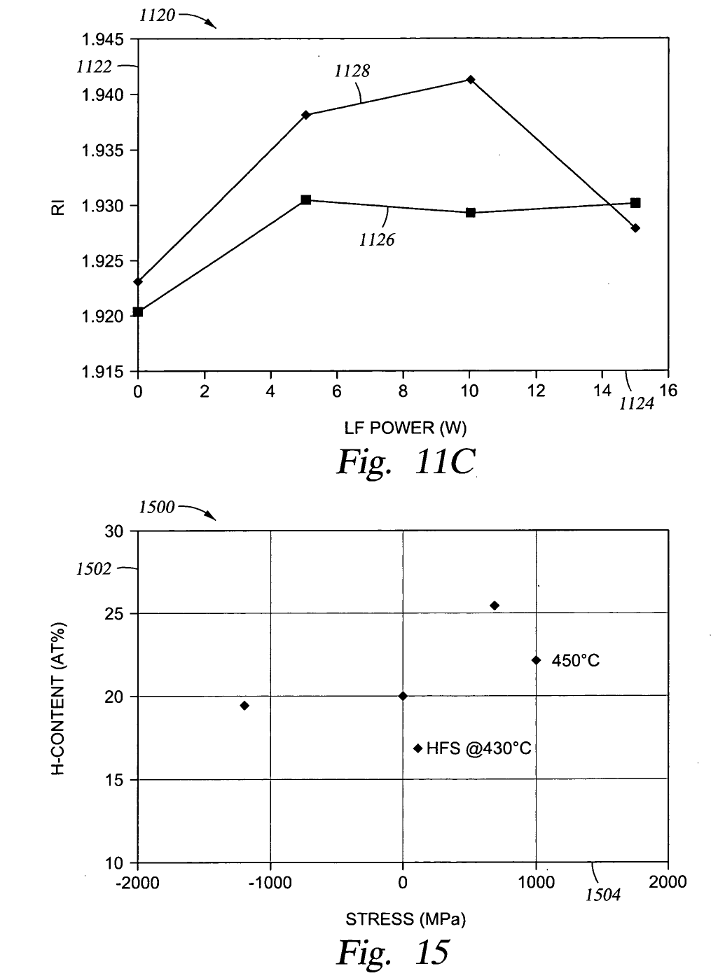

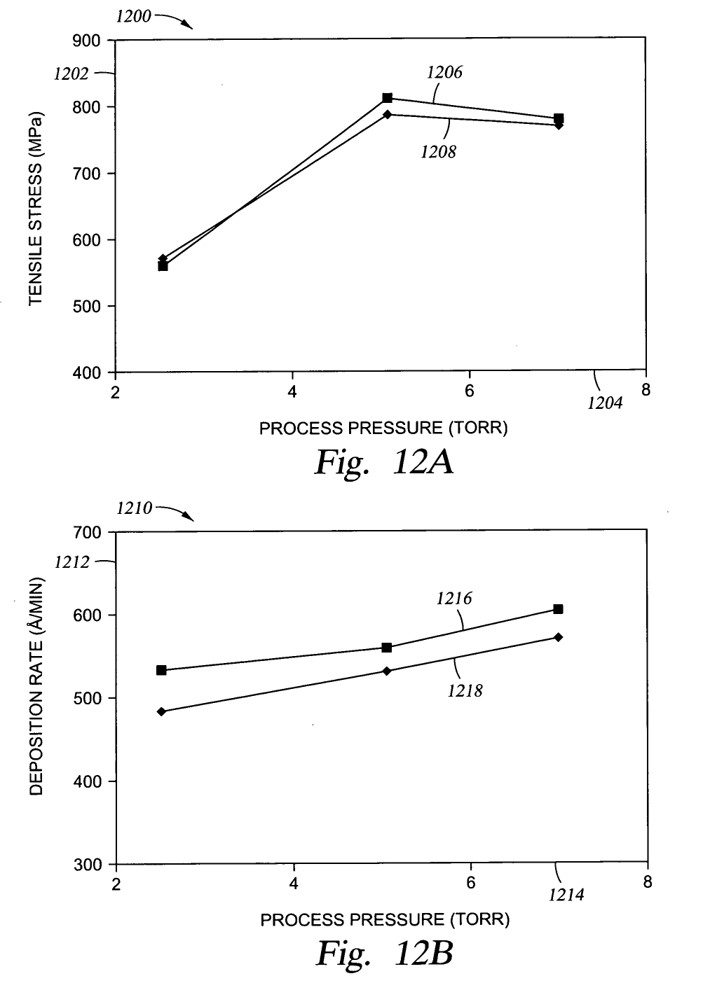

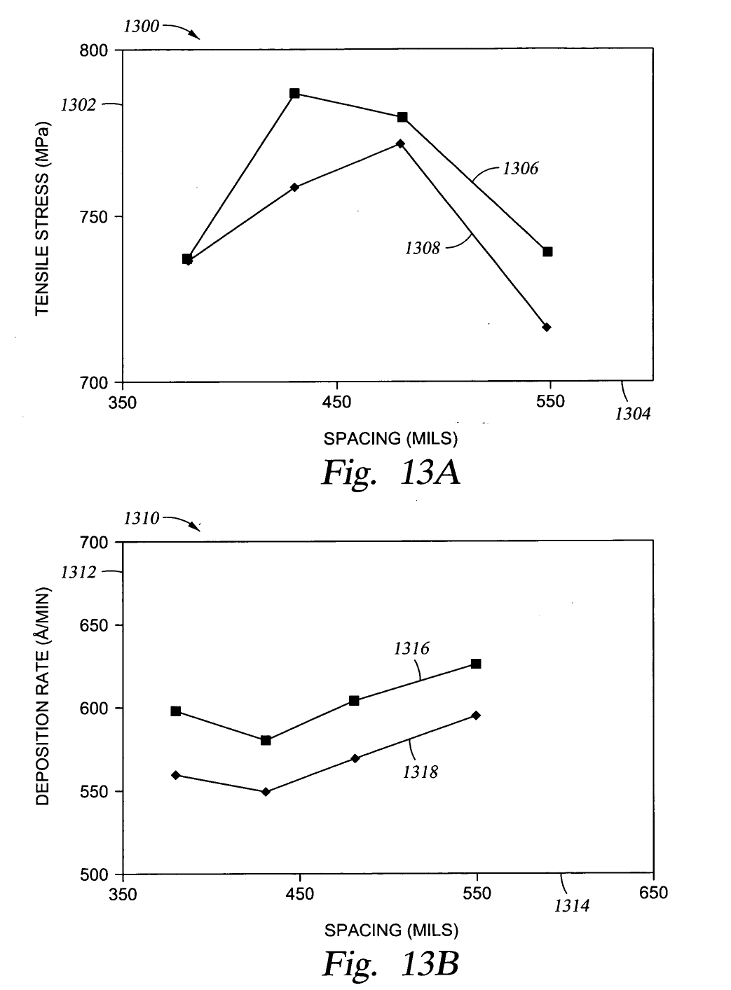

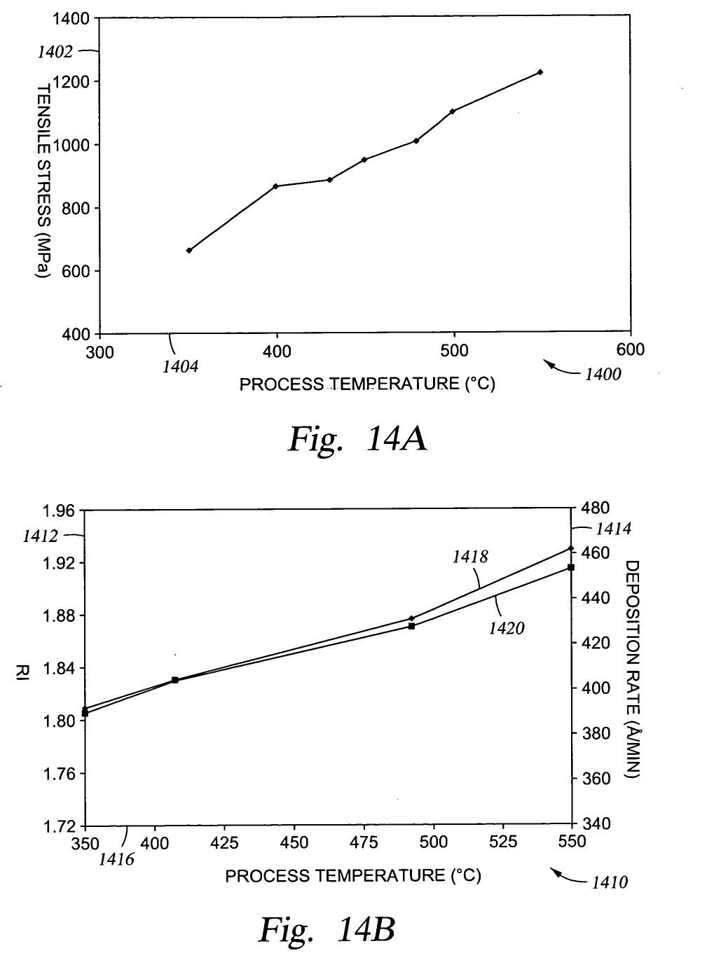

FIGS. 8 through 14 illustrate the effects on film stress and, in some cases, film deposition rate and refractive index, of increases in the following process parameters: 1) SiH₄ flow rate (FIGS. 8A-8C); 3) NH₃ flow rate (FIG. 9); 3) N₂ flow rate (FIGS. 10A and 101B); 4) low frequency power (FIGS. 11A-11C); 5) process chamber pressure (FIGS. 12A and 12B); 6) spacing between the faceplate and the heater within the processing chamber (FIGS. 13A and 13B); and 7) heater temperature (FIG. 14).

As discussed above, because high tensile stress can improve nMOS performance without negatively affecting pMOS performance, high tensile stress films are typically more desirable for increasing electron mobility in transistor applications. Therefore, the silicon nitride films represented in the examples shown in FIGS. 8 through 13 are films having stresses in the tensile range.

FIG. 8A is a graph 800 showing the stress on scale 802 of silicon nitride films deposited according to the present method, as a function of the SiH₄ flow on scale 804 during film deposition. Plots 806 and 808, respectively, represent the right side and left side of a 300-mm diameter silicon wafer, indicating uniformity across the substrate.

FIG. 8B is a graph 810 showing the deposition rate on scale 812 of silicon nitride films deposited according to the present method, as a function of the SiH₄ flow on scale 814 during film deposition. Plots 816 and 818, respectively, represent the right side and left side of a 300-mm diameter silicon wafer, indicating uniformity across the substrate.

FIG. 8C is a graph 820 showing the refractive index on scale 822 of silicon nitride films deposited according to the present method, as a function of the SiH₄ flow on scale 824 during film deposition. Plots 826 and 828, respectively, represent the right side and left side of a 300-mm diameter silicon wafer, indicating uniformity across the substrate.

The data in FIGS. 8A, 8B, and 8C were generated using a heater temperature of 400° C. (resulting in a substrate temperature of approximately 375° C.). These data indicate that, as the SiH₄ flow rate increases from 175 sccm to 330 sccm, the following trends appear: 1) film stress decreases (FIG. 8A); 2) silicon nitride film deposition rate gradually increases (FIG. 8B); and 3) refractive index increases (FIG. 8C).

FIG. 9 is a graph 900 showing the stress on scale 902 of silicon nitride films deposited according to the present method, as a function of the NH₃ flow on scale 904 during film deposition. Plots 906 and 908, respectively, represent the right side and left side of a 300-mm diameter silicon wafer, indicating uniformity across the substrate.

The data in FIG. 9 were generated using a heater temperature of 480° C. (resulting in a substrate temperature of approximately 455° C.). These data indicate that, as the NH₃ flow rate increases from 1500 sccm to 4750 sccm, film stress increases slightly.

FIG. 10A is a graph 1000 showing the stress on scale 1002 of silicon nitride films deposited according to the present method, as a function of the N₂ flow on scale 1004 during film deposition. Plots 1006 and 1008, respectively, represent the right side and left side of a 300-mm diameter silicon wafer, indicating uniformity across the substrate.

FIG. 10B is a graph 1010 showing the refractive index on scale 1012 of silicon nitride films deposited according to the present method, as a function of the N₂ flow on scale 1014 during film deposition. Plots 1016 and 1018, respectively, represent the right side and left side of a 300-mm diameter silicon wafer, indicating uniformity across the substrate.

The data in FIGS. 10A and 10B were generated using a heater temperature of 400° C. (resulting in a substrate temperature of approximately 375° C.). These data indicate that, as the N₂ flow rate increases from 2000 sccm to 6000 sccm, the following trends appear: 1) film stress increases (FIG. 10A); and 2) refractive index increases (FIG. 10B).

FIG. 11A is a graph 1100 showing the stress on scale 1102 of silicon nitride films deposited according to the present method, as a function of the low frequency power on scale 1014 applied during film deposition. Plots 1110 and 1108, respectively, represent the right side and left side of a 300-mm diameter silicon wafer, indicating uniformity across the substrate.

FIG. 11B is a graph 1110 showing the deposition rate on scale 1102 of silicon nitride films deposited according to the present method, as a function of the low frequency power on scale 1114 applied during film deposition. Plots 1116 and 1118, respectively, represent the right side and left side of a 300-mm diameter silicon wafer, indicating uniformity across the substrate.

FIG. 11C is a graph 1120 showing the refractive index on scale 1122 of silicon nitride films deposited according to the present method, as a function of the low frequency power on scale 1124 applied during film deposition. Plots 1126 and 1128, respectively, represent the right side and left side of a 300-mm diameter silicon wafer, indicating uniformity across the substrate.

The data in FIGS. 11A, 11B, and 11C were generated using a heater temperature of 400° C. (resulting in a substrate temperature of approximately 375° C.). These data indicate that, as the low frequency power increases from 0 W to 15 W, the following trends appear: 1) film stress decreases above 10 W power (FIG. 11A); 2) silicon nitride film deposition rate gradually increases (FIG. 11B); 3) refractive index does not vary significantly (FIG. 11C).

FIG. 12A is a graph 1200 showing the stress on scale 1202 of silicon nitride films deposited according to the present method, as a function of the process chamber pressure on scale 1204 during film deposition. Plots 1206 and 1208, respectively, represent the right side and left side of a 300-mm diameter silicon wafer, indicating uniformity across the substrate.

FIG. 12B is a graph 1210 showing the deposition rate on scale 1212 of silicon nitride films deposited according to the present method, as a function of the process chamber pressure on scale 1214 during film deposition. Plots 1216 and 1218, respectively, represent the right side and left side of a 300-mm diameter silicon wafer, indicating uniformity across the substrate.

The data in FIGS. 12A and 12B were generated using a heater temperature of 400° C. (resulting in a substrate temperature of approximately 375° C.). These data indicate that, as the process chamber pressure increases from 2.5 Torr to 7 Torr, the following trends appear:
1) film stress increases up to about 5 Torr, then decreases gradually (FIG. 12A); and
2) silicon nitride film deposition rate gradually increases (FIG. 12B).

FIG. 13A is a graph 1300 showing the stress on scale 1302 of silicon nitride films deposited according to the present method, as a function of the spacing between the faceplate and the heater within the processing chamber, on scale 1304. Plots 1306 and 1308, respectively, represent the right side and left side of a 300-mm diameter silicon wafer, indicating uniformity across the substrate.

FIG. 13B is a graph 1310 showing the deposition rate on scale 1312 of silicon nitride films deposited according to the present method, as a function of the spacing between the faceplate and the heater within the processing chamber, on scale 1314. Plots 1316 and 1318, respectively, represent the right side and left side of a 300-mm diameter silicon wafer, indicating uniformity across the substrate.

The data in FIGS. 13A and 13B were generated using a heater temperature of 400° C. (resulting in a substrate temperature of approximately 375° C.). These data indicate that, as the spacing between the faceplate and the heater increases from 375 mils to 550 mils, the following trends appear: 1) film stress increases, then decreases (FIG. 123); and 2) silicon nitride film deposition rate decreases slightly, then increases (FIG. 13B).

FIG. 14A is a graph 1400 showing the stress on scale 1402 of silicon nitride films deposited according to the present method, as a function of the heater temperature during film deposition, on scale 1404. The substrate temperature is typically about 25° C. less than the heater temperature.

FIG. 14B is a graph 1410 showing the refractive index 1412 and deposition rate 1414 of silicon nitride films deposited according to the present method, as a function of the heater temperature 1416 during film deposition. Plots 1418 and 1420, respectively, represent the refractive index and the deposition rate of the silicon nitride films.

The data in FIGS. 14A and 14B indicate that, as the deposition temperature increases from 350° C. to 550° C., the following trends appear: 1) film stress increases; 2) refractive index increases; and 3) deposition rate increases.

A summary of the trends illustrated graphically in FIGS. 8 through 14 is presented in Table VI, below.

TABLE VI
Summary of Trends in Silicon Nitride Deposition

| | | Film Deposition | |
|---|---|---|---|
| Process Parameter: | Film Stress | Rate | Refractive Index |
| Increased SiH₄ | Decreases | Increases | Increases |
| Flow | | | |
| Increased N₂ Flow | Increases | N/A* | Increases |
| Increased Low | Decreases | Increases | No significant |
| Frequency Power | | | effect |
| Increased Process | Increases | Increases | N/A* |
| Chamber Pressure | | | |
| Increased Spacing | Decreases | Increases | N/A* |
| Increased | Increases | Increases | Increases |
| Temperature | | | |

*N/A = Not available (not measured)

Table VII, below, shows the hydrogen content of silicon nitride films deposited according to the present method.

TABLE VII
Hydrogen Content of PECVD Deposited Silicon Nitride Films

| | Film Parameter | | | |
|---|---|---|---|---|
| | Sample A | Sample B | Sample C | Sample D |
| Substrate Diameter | 200 | 200 | 200 | 300 |
| (mm) | | | | |
| Deposition | 430 | 430 | 430 | 450 |
| Temperature (° C.) | | | | |
| Film Thickness (Å) | 3000 | 2800 | 2800 | 2200 |
| Film Stress | −1.2 GPa | 0 | 700 MPa | 1.0 GPa |
| Refractive Index | 1.94 | 1.96 | 1.90 | 1.94 |
| Density (g/cc) | 2.9 | 2.6 | 2.5 | 2.45 |
| % Hydrogen | 19.5 ± 1.4 | 20 ± 1.4 | 25.5 ± 1.8 | 22.2 ± 1.6 |

The data in Table VII are illustrated graphically in FIG. 15, which is a plot 1500 showing the % hydrogen content 1502 as a function of the film stress 1504 of silicon nitride films deposited according to the present method.

The data in Table VII and FIG. 15 indicate that the hydrogen content of films deposited by the present method remains consistent under constant deposition conditions. (Films having thicknesses in the 2000 Å to 3000 Å range were deposited to enable easy and consistent measurement of hydrogen content.) They hydrogen content of the film was measured using Nuclear Resonance Analysis (NRA).

The above described embodiments are not intended to limit the scope of the present invention, as one skilled in the art can, in view of the present disclosure, expand such embodiments to correspond with the subject matter of the invention claimed below.

1. A method of tuning the stress of a single-layer silicon nitride film during deposition on a substrate, comprising:
placing a substrate in a plasma-enhanced chemical vapor deposition (PECVD) chamber, wherein said PECVD chamber is capable of processing a substrate wafer having a diameter of about 200 mm, and wherein said PECVD chamber has a high frequency RF power input source operating at a frequency within the range of about 13 MHz to about 14 MHz, and a low frequency RF power input source operating at a frequency within the range of about 300 kHz to about 400 kHz;
setting said high frequency RF power input source to a nominal value within the range of about 10 W to about 200 W;
setting said low frequency RF power input source to a nominal value within the range of about 0 W to about 100 W;
setting said PECVD process chamber pressure to a nominal value within the range of about 2 Torr to about 10 Torr;
setting said PECVD heater to a temperature which will provide a substrate temperature having a nominal value within the range of about 375° C. to about 525° C.; and
depositing a silicon nitride film by chemical vapor deposition to have a thickness within the range of about 300 Å to about 1000 Å on said substrate in a single deposition step, whereby said deposited silicon nitride film has a stress having a nominal value within the range of about −1.4 GPa to about +1.5 GPa.

2. The method of claim 1, wherein said deposited silicon nitride film has a stress which ranges between about −1.4 GPa and about 0 MPa.

3. The method of claim 1, wherein said deposited silicon nitride film has a stress which ranges between about 0 MPa and about +1.5 GPa.

4. The method of claim 3, wherein said deposited silicon nitride film has a stress which ranges between about +800 MPa and about +1.5 GPa.

5. The method of claim 1, wherein said silicon nitride film is deposited at a substrate temperature within the range of about 375° C. to about 525° C.

6. The method of claim 5, wherein said silicon nitride film is deposited at a substrate temperature within the range of about 375° C. to about 455° C.

7. The method of claim 1, wherein said high frequency power input source is set to a nominal value within the range of about 30 W to about 100 W.

8. The method of claim 7, wherein said high frequency power input source is set to a nominal value within the range of about 30 W to about 80 W.

9. The method of claim 1, wherein said low frequency power input source is set to a nominal value within the range of about 10 W to about 50 W.

10. The method of claim 9, wherein said low frequency power input source is set to a nominal value within the range of about 10 W to about 40 W.

11. The method of claim 1, wherein said PECVD process chamber pressure is set to a nominal value within the range of about 2 Torr to about 6 Torr.

12. A method of tuning the stress of a single-layer silicon nitride film during deposition on a substrate, comprising:
placing a substrate in a plasma-enhanced chemical vapor deposition (PECVD) chamber, wherein said PECVD chamber is capable of processing a substrate wafer having a diameter of about 300 mm, and wherein said PECVD chamber has a high frequency RF power input source operating at a frequency within the range of about 13 MHz to about 14 MHz, and a low frequency RF power input source operating at a frequency within the range of about 300 kHz to about 400 kHz;
setting said high frequency RF power input source to a nominal value within the range of about 10 W to about 200 W;
setting said high frequency RF power input source to a nominal value within the range of about 0 W to about 100 W;
setting said PECVD process chamber pressure to a nominal value within the range of about 2 Torr to about 15 Torr;
setting said PECVD heater to a temperature which will provide a substrate temperature having a nominal value within the range of about 375° C. to about 525° C.; and
depositing a silicon nitride film by chemical vapor deposition to have a thickness within the range of about 300 Å to about 1000 Å on said substrate in a single deposition step, whereby said deposited silicon nitride film has a stress having a nominal value within the range of about −1.4 GPa to about +1.5 GPa.

13. The method of claim 12, wherein said deposited silicon nitride film has a stress which ranges between about −1.4 GPa and about 0 MPa.

14. The method of claim 12, wherein said deposited silicon nitride film has a stress which ranges between about 0 MPa and about +1.5 GPa.

15. The method of claim 14, wherein said deposited silicon nitride film has a stress which ranges between about +800 MPa and about +1.5 GPa.

16. The method of claim 12, wherein said silicon nitride film is deposited at a substrate temperature within the range of about 375° C. to about 525° C.

17. The method of claim 16, wherein said silicon nitride film is deposited at a substrate temperature within the range of about 375° C. to about 455° C.

18. The method of claim 12, wherein said high frequency power input source is set to a nominal value within the range of about 50 W to about 200 W.

19. The method of claim 18, wherein said high frequency power input source is set to a nominal value within the range of about 75 W to about 150 W.

20. The method of claim 12, wherein said low frequency power input source is set to a nominal value within the range of about 10 W to about 100 W.

21. The method of claim 20, wherein said low frequency power input source is set to a nominal value within the range of about 10 W to about 60 W.

22. The method of claim 12, wherein said PECVD process chamber pressure is set to a nominal value within the range of about 2 Torr to about 10 Torr.

23. A stress-tuned, single-layer silicon nitride film, wherein said film has a thickness within the range of about 300 Å to about 1000 Å, and wherein said film exhibits a stress within the range of about −1.4 GPa to about +1.5 GPa.

24. The stress-tuned, single-layer silicon nitride film of claim 23, wherein said film exhibits a stress within the range of about −1.4 GPa to about 0 MPa.

25. The stress-tuned, single-layer silicon nitride film of claim 23, wherein said film is tuned to have a stress within the range of about 0 MPa to about +1.5 GPa.

26. The stress-tuned, single-layer silicon nitride film of claim 25, wherein said film is tuned to have a stress within the range of about +800 MPa to about +1.5 GPa.

27. The stress-tuned, single-layer silicon nitride film of claim 23, wherein said film is deposited using plasma-enhanced chemical vapor deposition (PECVD).

28. A semiconductor processing chamber for performing plasma-enhanced chemical vapor deposition (PECVD), wherein said PECVD chamber includes a high frequency power input source operating at a frequency within the range of about 13 MHz to about 14 MHz, and a high frequency power input source operating at a frequency within the range of about 300 kHz to about 400 kHz, and wherein said chamber has the capability of depositing a film layer having a thickness of at least 100 Å in a single deposition step.

29. The processing chamber of claim 28, wherein reactive species within said chamber have a residence time of at least 9 seconds.

30. The processing chamber of claim 28, wherein said chamber has the capability of depositing a film layer having a thickness within the range of about 100 Å to about 1000 Å in a single deposition step.

31. The processing chamber of claim 30, wherein said chamber has the capability of depositing a film layer having a thickness within the range of about 300 Å to about 1000 Å in a single deposition step.

32. The processing chamber of claim 31, wherein reactive species within said chamber have a residence time within the range of about 15 seconds to about 100 seconds.

33. The processing chamber of claim 28, wherein said high frequency power input source utilizes an RF power within the range of about 10 W to about 200 W.

34. The processing chamber of claim 28, wherein said low frequency power input source utilizes an RF power within the range of about 0 W to about 100 W.

35. The processing chamber of claim 28, wherein said low frequency power input source is capable of being adjusted in increments of 0.1 W.

36. The processing chamber of claim 34, wherein said low frequency power input source is capable of being adjusted in increments of 0.1 W.

37. The processing chamber of claim 24, wherein said chamber is capable of being operated at a heater temperature which provides a substrate temperature having a nominal value within the range of about 375° C. to about 525° C.
